(19) United States
(12) Patent Application Publication
(10) Pub. No.: US 2013/0180575 A1
(43) Pub. Date: Jul. 18, 2013

(54) Structures for Solar Roofing

(71) Applicants: David B. Jackrel, Pacifica, CA (US); Darren Lochun, Mountain View, CA (US); Eric Prather, San Jose, CA (US)

(72) Inventors: David B. Jackrel, Pacifica, CA (US); Darren Lochun, Mountain View, CA (US); Eric Prather, San Jose, CA (US)

(73) Assignee: NANOSOLAR, INC., San Jose, CA (US)

(21) Appl. No.: 13/555,033

(22) Filed: Jul. 20, 2012

Related U.S. Application Data
(63) Continuation-in-part of application No. 12/116,932, filed on May 7, 2008.
(60) Provisional application No. 61/509,785, filed on Jul. 20, 2011.
(60) Provisional application No. 60/916,551, filed on May 7, 2007.

(51) Int. Cl. H01L 31/048; H01L 31/05

(52) U.S. Cl. CPC H01L 31/0483; H01L 31/0504
USPC 136/251

(57) ABSTRACT

A roofing element includes a solar cell array positioned in an opening in a top surface of a roofing material. The solar cell array has a plurality of low series resistance, solar cells, where the low series resistance is based on a metallization-wrap-through solar cell architecture. Each solar cell has a cell aspect ratio, and the solar cells are electrically connected in an electrical string configuration by a low resistance cell-to-cell bonding method. The opening of the roofing material has an aperture area, and the amount of aperture area covered by the solar cell array defines an aperture fill. The cell aspect ratio and the electrical string configuration are tailored to achieve a specified total current and total voltage for the solar cell array while optimizing the aperture fill.

### RELATED APPLICATIONS

This application: 1) claims priority to U.S. Provisional Patent Application No. 61/509,785 filed Jul. 20, 2011, entitled “Structures For Low Cost, Reliable Solar Roofing”; and 2) is a continuation-in-part of U.S. patent application Ser. No. 12/116,932 filed May 7, 2008, entitled “Structures For Low Cost, Reliable Solar Roofing,” which claims priority to U.S. Provisional Patent Application No. 60/916,551 filed May 7, 2007, entitled “Structures For Low Cost, Reliable Solar Roofing”; all of which are hereby incorporated by reference for all purposes.

### FIELD OF THE INVENTION

This invention relates generally to photovoltaic devices, and more specifically, to improved building-integrated photovoltaic devices.

### BACKGROUND OF THE INVENTION

Building-integrated photovoltaic (BIPV) roof tiles currently represent a small portion of the overall photovoltaic market, in spite of the seemingly compelling proposition of integrating an energy source into a roofing component. Market adoption has been slow due in part to the relatively high cost of roofing tiles integrated with PV modules. High cost is currently incurred since solar modules are not designed to serve as a bulk construction material, but rather integrated into a home as a custom electrical installation. There are several barriers within the current residential rooftop BIPV market that have kept the overall market small and limited product adoption.

One of these barriers comprises costly manufacturing processes whereby relatively expensive silicon wafers are interconnected with the often mismatched framework of a roofing tile. The solar cells are inherently costly, and their interconnection process takes time and incurs additional cost, increasing the total system cost.

Conventional BIPV roofing tile product has substantial dead space where the wafers do not fully occupy the area within the tile frame (the “open area”). This spatial inefficiency reduces the power density of the roofing tile, and requires additional tiles to be installed to achieve a particular power output for a given solar system.

Additionally, time-consuming installation processes for BIPV products such as roofing tiles, including extensive electrical wiring and mechanical interconnection between tiles, results in high system installation costs and makes operation and maintenance of installed systems cost-prohibitive.

Drawbacks associated with traditional photovoltaic solar tiles have limited the ability and financial rationale to install large numbers of BIPV roofing in a cost-effective manner. These traditional solar tile configurations are also constrained by conventional design methodology that limits the modules to certain materials and inherits a large number of legacy parts.

### SUMMARY OF THE INVENTION

A roofing element includes a solar cell array positioned in an opening in a top surface of a roofing material. The solar cell array has a plurality of low series resistance solar cells, where the low series resistance is based on a metallization-wrap-through (MWT) solar cell architecture. Each solar cell has a cell aspect ratio, and the solar cells are electrically connected in an electrical string configuration by a low resistance cell-to-cell bonding method.

The opening of the roofing material has an aperture area, and the amount of aperture area covered by the solar cell array defines an aperture fill. The cell aspect ratio and the electrical string configuration are tailored to achieve a specified total current and total voltage for the solar cell array while optimizing the aperture fill.

### BRIEF DESCRIPTION OF THE DRAWINGS

A further understanding of the nature and advantages of the invention will become apparent by reference to the remaining portions of the specification and drawings.

FIG. 1 is a perspective view of a photovoltaic roofing element according to one embodiment.

FIG. 2 is a perspective view of a photovoltaic roofing element according to another embodiment.

FIG. 3 is a perspective view of a photovoltaic roofing element according to a yet further embodiment.

FIGS. 4A-4B show a cross-sectional view and a plan view, respectively of an exemplary metal-wrap-through solar cell in one embodiment.

FIG. 5 illustrates an exemplary cross-sectional view of interconnections between metal-wrap-through solar cells.

FIGS. 6A-6C depict one embodiment of a roofing element with a solar cell array.

FIGS. 7A-7C depict another embodiment of a roofing element with a solar cell array, showing a change in aperture fill.

FIGS. 8A-8C are a further embodiment of a roofing element with a solar cell array.

FIGS. 9A-9C are a yet further embodiment of a roofing element with a solar cell array.

FIGS. 10A-10C show another embodiment of a roofing element with a solar cell array, using a larger solar cell.

FIGS. 11A-11C illustrate an embodiment of a roofing element with a solar cell array using smaller solar cells connected in series.

FIGS. 12A-12C are a similar embodiment to FIGS. 11A-11C but connected in two parallel strings.

FIGS. 13A-13C show an embodiment of a roofing element with a solar cell array having a greater aperture fill compared to FIG. 7C.

### DESCRIPTION OF THE SPECIFIC EMBODIMENTS

It is to be understood that both the foregoing general description and the following detailed description are exemplary and explanatory only and are not restrictive of the invention, as claimed. It may be noted that, as used in the specification and the appended claims, the singular forms “a”, “an” and “the” include plural referents unless the context clearly dictates otherwise. Thus, for example, reference to “a material” may include mixtures of materials, reference to “a compound” may include multiple compounds, and the like. References cited herein are hereby incorporated by reference in their entirety, except to the extent that they conflict with teachings explicitly set forth in this specification.

In this specification and in the claims which follow, reference will be made to a number of terms which shall be defined to have the following meanings:

“Optional” or “optionally” means that the subsequently described circumstance may or may not occur, so that the description includes instances where the circumstance occurs and instances where it does not. For example, if a device optionally contains a feature for an anti-reflective film, this means that the anti-reflective film feature may or may not be present, and, thus, the description includes both structures wherein a device possesses the anti-reflective film feature and structures wherein the anti-reflective film feature is not present.

The present invention provides for low series resistance solar cells which are integrated into roofing materials. The solar cells are flexible in size and aspect ratio, and thus the surface area of the inlays can be almost completely be covered by active cells for all existing conventional tile geometries. In comparison with silicon wafer cells that in most roof tile sized modules might only fill part of the available area, similar overall efficiency can therefore be achieved with the customizable solar cells of the present disclosure, at substantially lower per watt cost. The output current of the tile can be tuned for optimal system efficiency by varying cell size, with the system voltage being decided by the amount of tiles in series. Overall, this results in lower material cost and a flexible design allowing installers to rapidly and cost-efficiently deploy solar roofing at a large scale.

In one embodiment of the present invention, a photovoltaic roofing structure is provided comprising a roofing tile having a top surface, and an opening—such as a recessed portion—in the top surface. A photovoltaic module made of an array low resistance series solar cells may be tailored in size to fit within the recessed portion of the tile. Optionally, instead of a tile, other roofing material may be used. Optionally, in other embodiments, instead of a roof, the module is integrated with other non-roof building material.

The present invention also provides for an improved BIPV roofing tile design that simplifies the configuration and reduces the materials costs associated with such photovoltaic roofing elements. Although not limited to the following, these improved roofing element designs are well suited for installation at dedicated sites where redundant elements can be eliminated and where some common elements or features may be shared by many modules. Embodiments of the present invention may be adaptable for roll-to-roll and/or batch manufacturing processes. At least some of these and other objectives described herein will be met by various embodiments of the present invention.

Large scale solar panels distribute the cost of one set of electrical connectors and mounting over a larger quantity of cells. This has led to solar module sizes that, optimized for commercial rooftops and green field installations, are significantly larger than a standard roof tile format, which over decades has been fine-tuned for optimum balance between installation effort and flexibility. As multi-faceted residential roofs have gables, chimneys and partial shading, which all restrict the area where solar modules can be mounted, a smaller form factor is desirable to maximize the flexibility of installation. The present design is a foil substrate which can be cut into a wide range of cell formats, increasing the format options to fit into a single tile.

As the solar tiles replace the existing conventional roof tiles and mount onto the existing roof battens, no additional on-roof mounting infrastructure is required. Given the ease of use, the same roofers that install regular tiles can install the solar roof tiles, as the installation follows the same rules, on the same level of care. Additional installation cost is limited to an electrician connecting the start and end tiles of a row to the inverter or to each other. Sales and distribution channels are equivalent to existing roofing product channels.

Traditional solar cell manufacturing typically creates a solar cell of a specific current and voltage. Tailoring of these parameters is usually done at the device level. Solar modules, if they are created from cells rather than monolithically integrated, have specific size and connectivity and inherently do not lend themselves to variations in size and architecture. An example of this is the silicon solar cell that is formed from a specific size silicon ingot. In theory the size can be varied, but the cost associated with the wafer makes variations away from the maximum optimal configuration uneconomic. Silicon solar found in consumable electronics devices (watches, calculators, etc.) are typically formed from wafers of high defects or broken wafers. Another example is a thin film solar cell on a stainless steel substrate. This type of product is able to be formed into varying dimensions but the range of dimensions that is electrically relevant is severely limited by the lower conductivity of stainless steel compared to aluminum.

### Photovoltaic Roofing Element

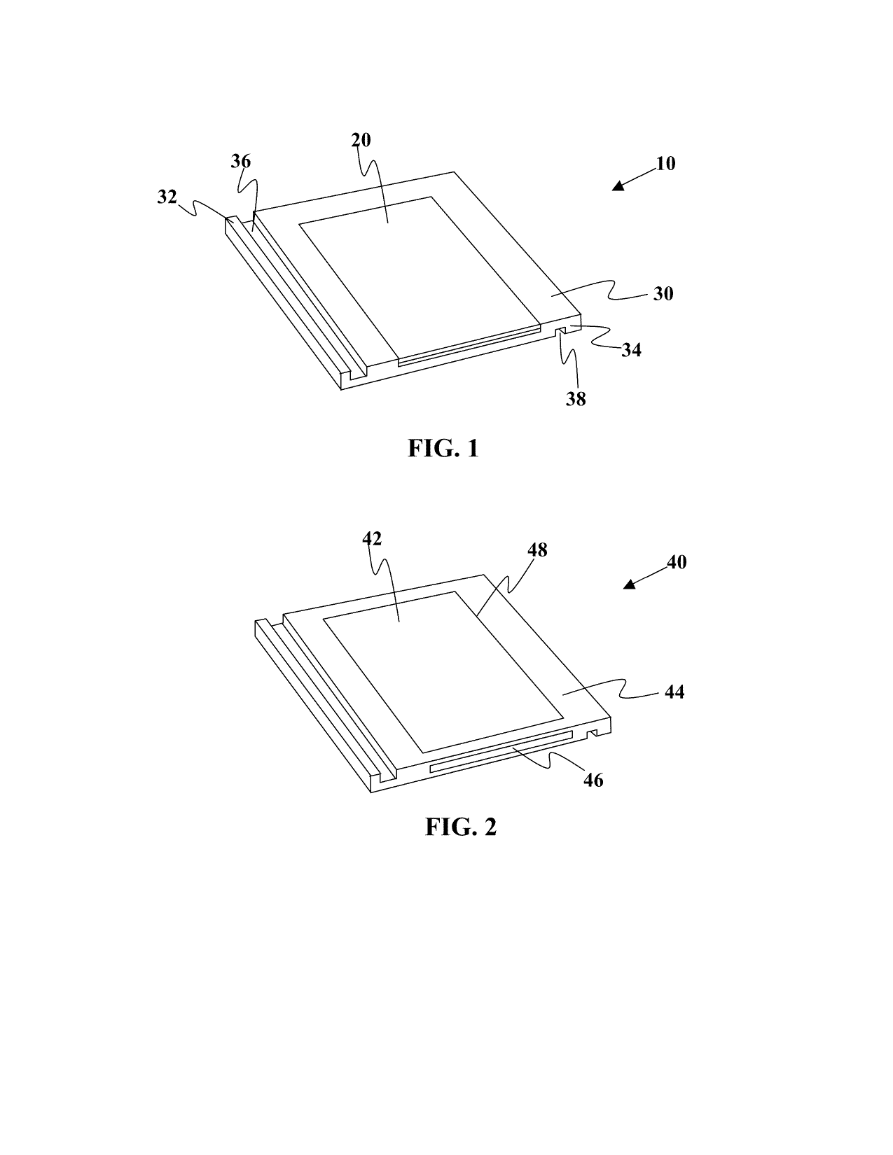

Referring now to FIG. 1, one embodiment of a photovoltaic roofing element 10 will now be described. Although the present invention is described in the context of ceramic or slate roofing tiles, it should be understood that the present invention is applicable to various other types of roofing elements.

As seen in FIG. 1, the photovoltaic module 20 is housed in a recess or opening formed in the tile portion 30 of the photovoltaic roofing element 10. The tile portion 30 remains the main structural element of the photovoltaic roofing element 10. In the present embodiment, the photovoltaic module 20 is an inlay element that is supported by the tile 30. The tile 30 comprises typical materials used for roofing tiles, which may include but is not limited to clay, ceramic, concrete, copper, steel, stainless steel, aluminum, iron, stone, glass, marble, fiberglass, granite, porcelain, or the like. The tile 30 may be glazed or otherwise surface-treated to improve the durability, increase heat transfer properties, improve visual appearance, increase stain resistance, reduce efflorescence, increase or reduce surface smoothness, or the like. Although not limited to the following, the tile 30 may include matching tongues 32, 34 and grooves 36, 38 on the edges of the tiles to facilitate placement and connection with adjacent tiles (solar or non-solar).

As seen in FIG. 1, the upper surface of tile 30 remains visible even with the photovoltaic module 20 is inlaid in the tile 30. The tile 30 retains its functionality as a roofing tile. Although not limited to the following, the tile 30 has an exterior outline shaped like the other non-photovoltaic tiles used on the roof, which the installers are comfortable handling in a manner similar to other roofing tiles. By way of nonlimiting example, the tile 30 may be comprised of the same material as the surrounding non-photovoltaic tiles. This allows the tile 30 to blend visually with other non-photovoltaic tiles as they comprise substantially the same material.

Advantageously in one embodiment of the present invention, the ratio of the weight of the module 20 to the weight of the tile 30 may be equal to, less than, or more than that of the tile. The overall weight of the combination is less than that of a roofing tile of the same size but providing coverage without the photovoltaic module. Optionally, the overall weight is less than that of a roofing tile of the same size made of a Class A fire rated material but providing roofing coverage without the photovoltaic module. In one embodiment, the ratio of the weight of the tile to the weight of the photovoltaic module is in the range of about 3:1 to 1:1. In one embodiment, the ratio of the weight of the tile to the module is in the range of about 5:1 to 1:1. In another embodiment, the range is about 10:1 to 1:1. These ratios allow for the photovoltaic module to contribute relatively less to the overall weight of the combined BIPV tile. The tile remains first and foremost a Class A fire-rated material. Even if the inlaid solar module is itself damaged in some way, the present embodiment of tile 30 will continue to retain is inherent weatherproofing and fireproofing capability. In this manner, the bulk of the weight still comes from the tile material itself and not from the module.

Referring now to FIG. 2, yet another embodiment of the present invention will now be described. FIG. 2 shows a photovoltaic roofing element 40 comprised of a photovoltaic module 42 and a roofing tile 44. This photovoltaic roofing element 40 differs from photovoltaic roofing element 10 in that the photovoltaic module 42 slides through a slot 46 into a channel defined within the tile 44. This slot 46 allows for increased mechanical overlap to hold the photovoltaic module 42 in the tile due to the overhang created by a portion of the tile 44. This may be created by having the opening 48 above the module 42 that exposes the module to the sunlight be smaller than the overall dimensions of the module.

It should be understood that after the module is inserted into the tile 44, the slot 46 may be filled or sealed with material to close the slot 46. In some embodiments, only enough sealing material is provided to prevent the module from sliding out of the tile 44, without actually completely sealing the slot 46. In alternative embodiments, a mechanical stopper, mechanical attachment, or other device such as a set screw may be used to secure the tile in position.

Optionally, in some embodiments, there is no slot 46. In such embodiments, the module 42 is integrally molded with the tile during tile fabrication and there is no need for a slot to insert the module 42 at a later time. Although not limited to the following, the module may be loosely held therein to allow for coefficient of thermal expansion (CTE) differences between the module 42 and the tile 44.

In other embodiments, a shingle or other modular roofing construct may be used instead of a tile as a roofing material. The roofing material may be rigid or flexible as needed to meet the requirements of the roof on which the material is to be installed.

While the appearance of most solar roof modules stands in stark contrast with the surrounding roof surface, the solar tiles may use frames of the material, color and texture identical to that of the surrounding tiles. The solar inlays have no frame, visible electrical contacts or mounting hardware. Shape and style match the conventional tile, and given the flexible cell substrate, an arced glass top on the solar insert is possible to harmonically ‘weave’ solar inlays into S-shaped tiles. A uniform layout of grids and rows of solar tiles becomes feasible on a roof by offering matching dummy cells that look like solar tiles for shaded areas. The juxtaposition of the traditional material and solar glass inserts creates an aesthetic tension that does not try to hide the solar panels, but frames them into a bold statement.

### Heat Dissipation

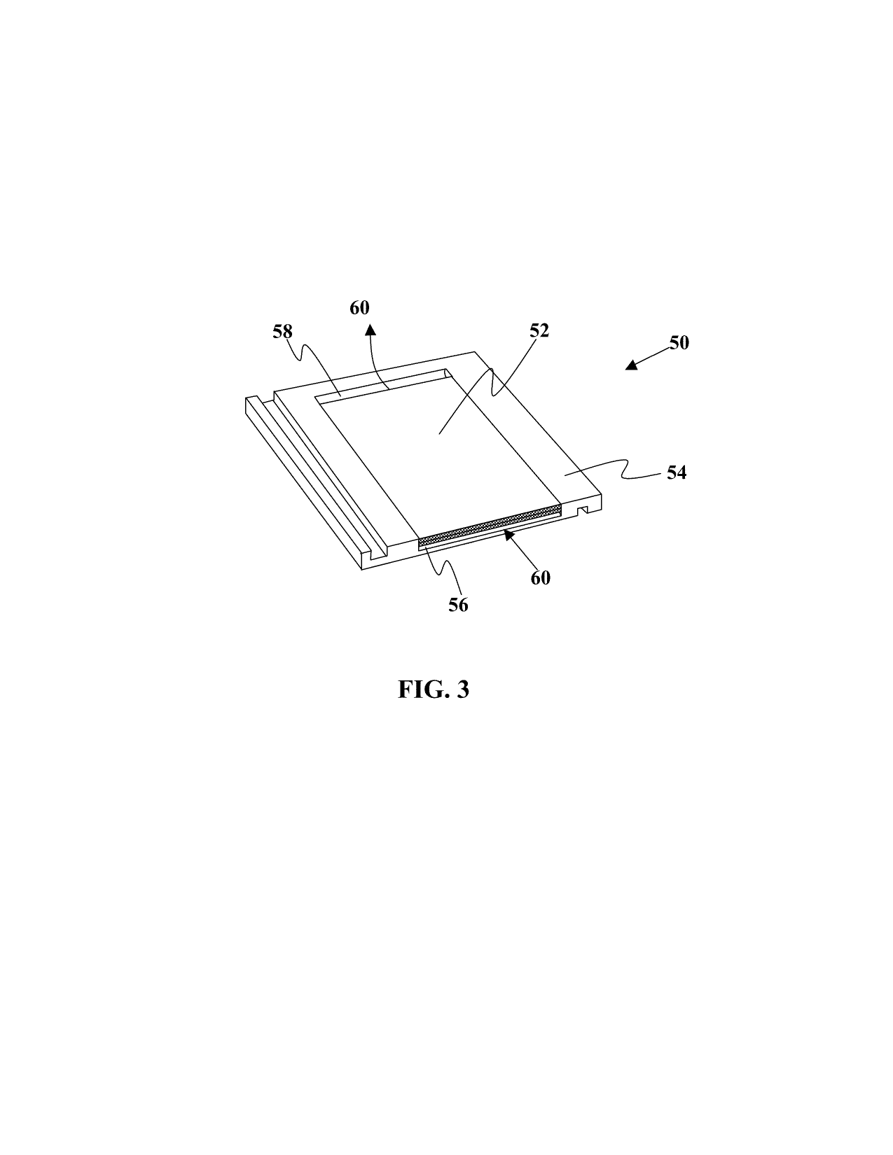

Referring now to FIG. 3, a still further embodiment of the present invention will now be described. The photovoltaic roofing element 50 is designed to address thermal issues associated with putting a photovoltaic module 52 in a roof shingle or tile 54. Although increased sunlight intensity usually means increased electrical output from a solar device, increasing sunlight intensity also usually means increased normal operating cell temperature (NOCT) of the solar cell. For solar cells and solar cell modules, excessive heat decreases the conversion efficiency of these devices. NOCT for most solar cell modules is around 47° C. Many solar cell modules lose about 0.5% efficiency for every degree of increase in NOCT. A variety of factors may contribute to increased NOCT such as greater ambient air temperature during the day, increased temperature of the solar module itself from extended sun exposure, or radiant heat from ground surfaces and other nearby surfaces which may emit heat generated from sun exposure.

This thermal issue may be of particular concern for BIPV devices. Most conventional solar modules are ground mounted or roof mounted in a manner sufficiently spaced above the ground or roof surface such that the underside of the module is not in such close proximity to a thermal mass. This distance allows for decreased operating temperature as various factors such as wind and distance from radiant heat sources allow the modules to be at a lower temperature. With a building integrated photovoltaic material, the design constraints are such that the module is necessarily in relatively close proximity to a radiant heat source or thermal mass such as the tile itself

FIG. 3 shows one technique for addressing the increased heat dissipation needs. FIG. 3 shows an embodiment of a photovoltaic roofing member 50 with a photovoltaic module 52 integrated with a shingle or tile 54. The module 52 is positioned such that a channel or void space is defined between the bottom surface of the module 52 and the tile 54. Opening 56 is an open space along the lower face of module 52, while opening 58 is an opening at one end of the module 52. Openings 56 and 58 allow air to flow as indicated by arrows 60 (bottom up). Optionally, the air may flow in reverse (top down) depending on the direction of the wind.

### Metal Wrap Through and Cell Interconnection

FIGS. 4A and 4B show a cross-section and a top view, respectively of an exemplary solar cell 100 having a metallization-wrap-through (MWT) architecture. Details of these cells can be found in U.S. Pat. No. 8,198,117, entitled “Photovoltaic Devices with Conductive Barrier Layers and Foil Substrates,” which is fully incorporated herein by reference for all purposes. In the cross-sectional view shown in FIG. 4A, the MWT cell 100 includes photovoltaic films 110, a cell foil 120, an insulating layer 130, and a back foil 140. Photovoltaic films 110 may include, for example, a transparent conducting layer (e.g., Al:ZnO, i:ZnO) and an active layer (e.g., copper-indium-gallium-selenium “CIGS”). Cell foil 120 serves as a bottom electrode, and may be made from, for example, aluminum, which may be on the order of 100 microns thick. Aluminum enables a solar cell array of low series resistance, as the resistivity of aluminum is approximately 26.5 nΩ-m compared to, for example, stainless steel with a resistivity of 720 nΩ-m. Insulating layer 130 may be, for example, polyethylene terephthalate (PET) on the order of 50 microns thick, and back foil 140 may be a back plane such as aluminum on the order of 25 microns thick. In some embodiments, the back foil 140 is in the form of a thin aluminum tape that is laminated to the cell foil 120 using an insulating adhesive as the insulating layer 130. Low resistance is intrinsic to the parallel current method of the MWT solar cell. In one embodiment, the series resistance is less than 1 Ohm/cm². The MWT architecture may be created by roll-to-roll processing, such as on an aluminum foil substrate and a second foil. In some embodiments, the solar cells 100 are grown on a highly conductive substrate, such as a substrate having a resistivity less than 1×10⁻⁸ Ohm-m.

Also shown in FIGS. 4A-4B is a conductive trace 150 connecting to a via 160. Since the conductive back foil 140 carries electrical current from one device module to the next, the conductive trace 150 can be a relatively thin “finger” while avoiding thick “busses.” This reduces the amount of shadowing due to the busses and also provides a more aesthetically pleasing appearance to the solar cell 100. The electrical traces for the device need only provide sufficiently conductive traces 150 to carry current to the vias 160. Via 160 forms a channel through the transparent conducting layer and the active layer of photovoltaic films 110, through the flexible bulk conductor of cell foil 120, and the insulating layer 130. In this manner an essentially electrically parallel building block is created within the cell that is able to facilitate changes in cell dimension without compromising the overall cell performance and integration. An insulating material coats sidewalls of the via 160, and a plug made of an electrically conductive material at least substantially fills the channel and makes electrical contact between the transparent conducting layer of photovoltaic films 110 and the back foil 140. The via 160 may be, for instance, between about 0.1 millimeters in diameter and about 1.5 millimeters in diameter, and may include a closed-loop trench that surrounds a portion of the transparent conducting layer, active layer, and a bottom electrode. The conductive traces 150 may form rectangular patterns extending from the vias 160, as shown FIG. 4B, which depicts a full solar cell sheet as well as a close-up view. However, a variety of patterns or orientations for the conductive traces 150 may be used so long as the lines are approximately equidistant from each other (e.g., to within a factor of two). For example, in alternative embodiments the electrical traces may fan out radially from the contacts 120, or may form a “watershed” pattern in which thinner traces branch out from thicker traces that radiate from the vias 160. The number of conductive traces 150 connected to each via 160 may be more or less than the number shown in FIG. 4, such as having one more, two more, three more, or the like.

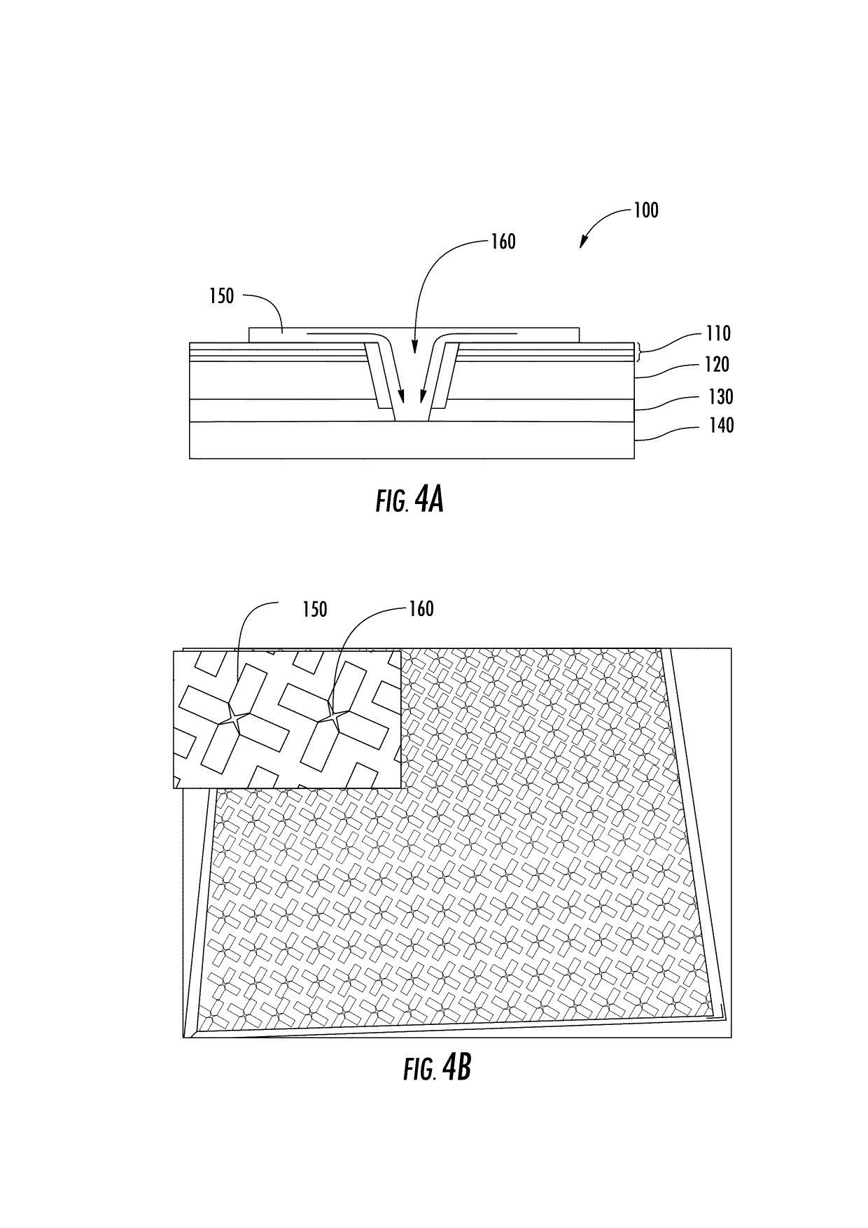

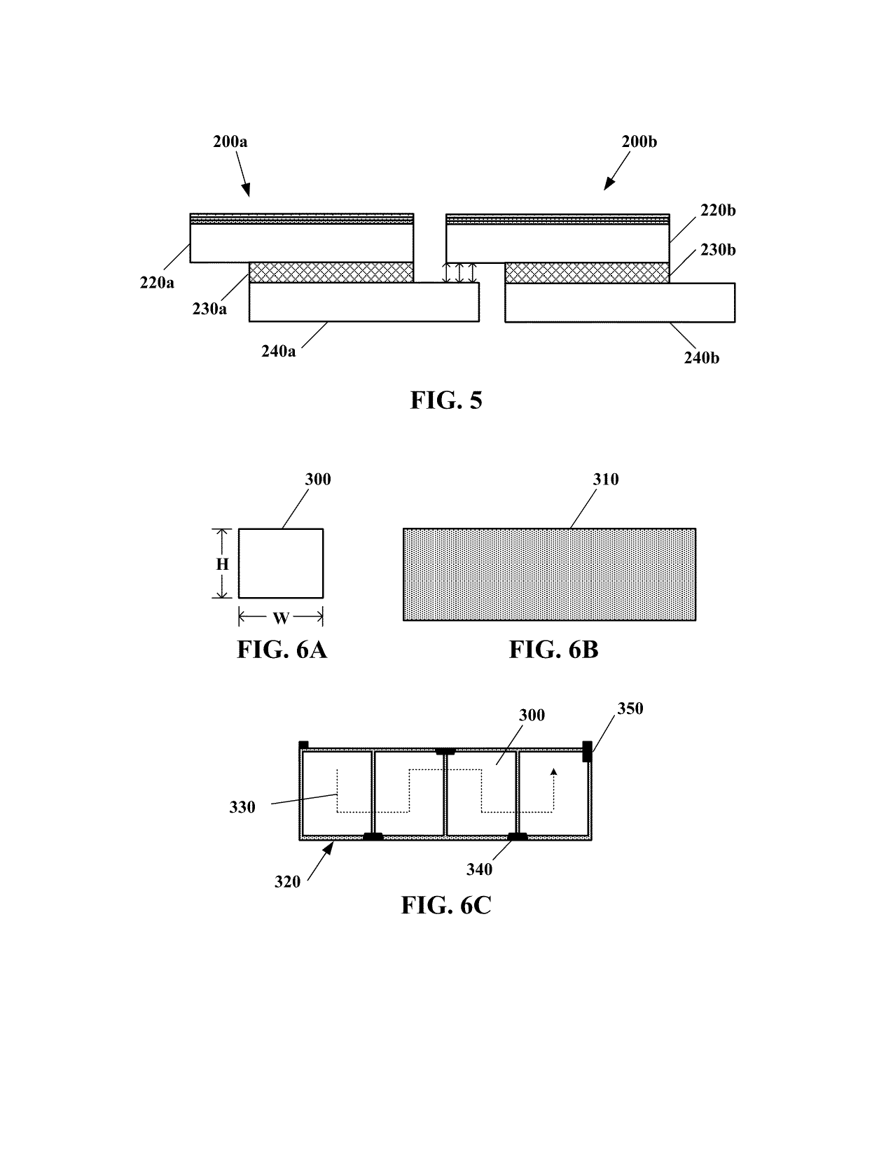

FIG. 5 shows an exemplary embodiment for interconnecting two MWT type solar cells 200a and 200b. The “offset” nature of the front and back foils of the MWT cells 200a and 200b provide the ability to form cell-to-cell connections. Cell foil 220a and insulating layer 230a of cell 200a have been cut back, as have insulating layer 230b and back foil 240b of cell 200b. As a result, cell foil 220b of cell 200b overhangs back foil 240a of cell 200a, enabling cell-to-cell bonding of the solar cells in a “shingle” type manner. The bonding (indicated by the double-sided arrows) between the cells 200a and 200b may be made in a low resistance manner, such as by laser welding, ultrasonic welding, solder bonding, and conductive adhesive bonding.

The metal-wrap-through architecture described in FIGS. 4A-4B and 5 enables solar cells to be cut into custom sizes—that is, various cell areas and aspect ratios—as specified by design requirements of a customer. The amenability of the technology to roll-to-roll processing allows the cells to be produced in large sheets, such as on the order of one square kilometer, which can then be cut into customized sizes and shapes as needed. Embodiments of the present invention may overcome the drawbacks of conventional devices by sizing and cutting cells to the exact dimensions of the inlay area within a carrier frame, resulting in nearly 100% inlay coverage. Optionally, some embodiments may use sizes that provide, for example, at least 95% inlay coverage, or at least 90% inlay coverage. Balancing the inlay size with the aesthetic requirements of the residential rooftop market, this may maximize power density in a given rooftop installation. Success with this technology improvement opportunity may impact the key performance factor (KPP) of Power Density.

The metallization-wrap-through type solar cells described herein facilitate relatively low cost manufacture of large-scale arrays of series-connected optoelectronic devices. Larger devices may be connected in series due to the reduced sheet resistance as a result of the connection between back planes and the transparent conducting layers through the contacts that penetrate the layers of the device modules. The conductive traces can further reduce sheet resistance. Larger devices can be arrayed with fewer connections.

It should also be understood that some embodiments may include diodes in the cells or optionally, only diodes are used to protect strings not cells. Diodes may include those described in PCT patent application No. PCT/US10/46877, which is fully incorporated herein by reference for all purposes.

Although glass is the layer most often described as the top layer for the module in the present disclosure, it should be understood that other material may be used and some multi-laminate materials may be used in place of or in combination with the glass. Some embodiments may use flexible top layers or coversheets. There may be anti-reflective or other surface treatments of the top layer. By way of nonlimiting example, the backsheet is not limited to rigid modules and may be adapted for use with flexible solar modules and flexible photovoltaic building materials. Embodiments of the present invention may be adapted for use with superstrate or substrate designs.

Details of modules with thermally conductive backplanes and heat sinks can be found in commonly assigned U.S. Pat. No. 7,985,919 entitled “Thermal Management for Photovoltaic Devices,” which is fully incorporated herein by reference for all purposes. Pottant materials which are used may be made more thermally conductive based on techniques shown in U.S. Pat. No. 7,985,919. The use of a conductive foil also provides a module back layer with sufficiently high thermally conductivity to improve heat transfer out of the module. Other backsheet materials may also be used and is not limited to glass only embodiments.

Furthermore, those of skill in the art will recognize that variations to the type of solar cell material and/or architecture are possible. For example, an absorber layer in the solar cell may be an absorber layer comprised of silicon, amorphous silicon, organic oligomers or polymers (for organic solar cells), bi-layers or interpenetrating layers or inorganic and organic materials (for hybrid organic/inorganic solar cells), dye-sensitized titania nanoparticles in a liquid or gel-based electrolyte (for Graetzel cells in which an optically transparent film comprised of titanium dioxide particles a few nanometers in size is coated with a monolayer of charge transfer dye to sensitize the film for light harvesting), copper-indium-gallium-selenium (for CIGS solar cells), CdSe, CdTe, Cu(In,Ga)(S,Se)₂, Cu(In,Ga,Al)(S,Se,Te)₂, and/or combinations of the above, where the active materials are present in any of several forms including but not limited to bulk materials, micro-particles, nano-particles, or quantum dots. The CIGS cells may be formed by vacuum or non-vacuum processes. The processes may be one stage, two stage, or multi-stage CIGS processing techniques. Additionally, other possible absorber layers may be based on amorphous silicon (doped or undoped), a nanostructured layer having an inorganic porous semiconductor template with pores filled by an organic semiconductor material (see e.g., U.S. Pat. No. 6,946,597 entitled “Photovoltaic Devices Fabricated By Growth from Porous Template” which is incorporated herein by reference), a polymer/blend cell architecture, organic dyes, and/or C₆₀ molecules, and/or other small molecules, micro-crystalline silicon cell architecture, randomly placed nanorods and/or tetrapods of inorganic materials dispersed in an organic matrix, quantum dot-based cells, or combinations of the above. Many of these types of cells can be fabricated on flexible substrates, including other non-CIGS thin-film solar cells.

Although the cells as shown as being planar in shape, those of round, tubular, rod or other shapes are not excluded. Some embodiments may also use internal reflectors positioned between cells to improve light collection. Some embodiments may have the cells formed directly on a glass surface of the module without an encapsulant layer between one layer of the glass and the cell.

### Solar Cell Arrangement in Roofing Elements

FIGS. 6-13 illustrate embodiments of solar cells arrays that are sized and arranged in various configurations for optimizing the amount of aperture area in a roofing element covered by the solar cell array. In addition, the electrical string configuration—such as in series or parallel—of the cells may be tailored to achieve a specified total current and total voltage for the solar cell array. The term “aperture fill” for the purposes of this disclosure shall describe the amount of an aperture area, where the aperture area is the opening in a roofing element in which a solar cell array is to be housed, which is covered by the solar cell array. The solar cells of the present embodiments are shown to be of certain sizes, but it should be understood that other sizes can also be manufactured to maximize the fill.

FIG. 6A shows a solar cell 300, and FIG. 6B shows an aperture area 310 representing the opening of a roofing material, such as the tiles of FIGS. 1-3. Aperture area 310 may have a glass panel over the cells placed within it. Solar cell 300 has a width “W” and height “H,” where the width is determined as the in-plane edges of the cell that form the cell-cell or cell to terminal connections. The width and height of the solar cell determine an aspect ratio, defined as the width divided by the height, which may be less than or greater than 1. In some embodiments the aspect ratio may range from as low as 0.2, such as in the case of a vertical strip, up to a value of 4, such as for a horizontal strip. However, other aspect ratios beyond this range are possible. In the embodiment of FIG. 6A, the solar cell 300 has a height of 5.31 inches and a width of 6.46 inches, where the terminal edges are on the shorter side. In FIG. 6C, a roofing element assembly 320 has an array of four cells connected in series, as indicated by dotted line 330. Cross-connectors 340 provide electrical connections between the solar cells 300, and exit ribbons 350 serve as electrical terminals for the array at either end of the roofing element 320. The exit ribbons 350, which are located at the long ends of the assembly 320, may be coupled to the array by a low resistance bonding method such as, but not limited. to, laser welding, ultrasonic welding, solder bonding, or conductive adhesive bonding. In other embodiments, other types of electrical terminals may be used instead of exit ribbons, such as those described in Stancel et al., U.S. patent application Ser. No. 12/116,932 can be seen in FIG. 6C that the size and aspect ratio of the solar cells 300 have been customized to fit the aperture 310, resulting in approximately a 98% aperture fill. If the individual solar cell 300 has a voltage “V” of Vₘₚₚ˜0.45 volts (V) and a current “I” of Iₘₚₚ˜5.75 amperes (A), the series connection of the four solar cells 300 in this embodiment results in a Vₜₒₜₐₗ of 2 V and an Iₜₒₜₐₗ of 5.75 A.

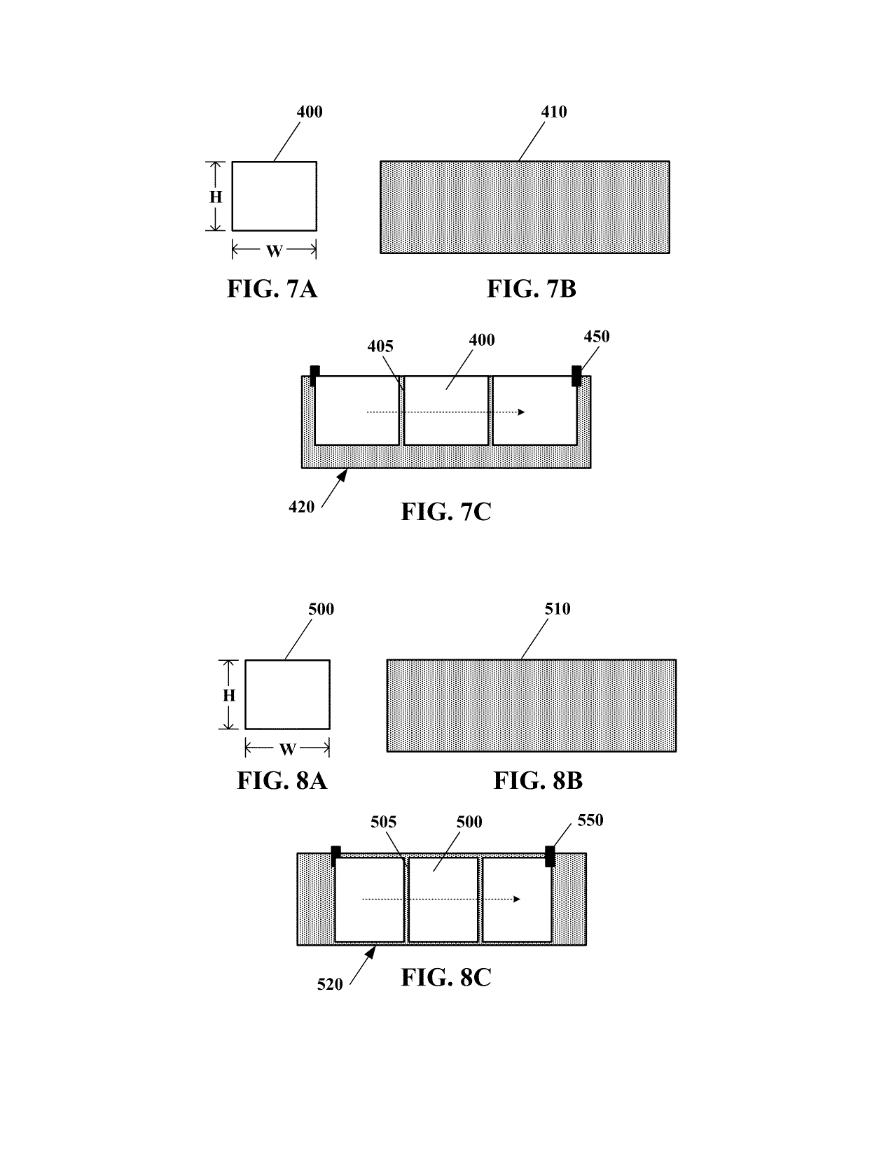

FIG. 7A shows a solar cell 400 having the same size as cell 300 in FIG. 6A; that is, H=5.31″, W=6.46″, and the same cell voltage and current of Vₘₚₚ˜0.45 V and Iₘₚₚ˜5.75 A. Aperture area 410 of FIG. 7B is of a different size than aperture area 310 of FIG. 6B, and may represent, for example, a shingle with glass. In FIG. 7C, the cells 400 in the assembly 420 are rotated 90 degrees with respect to the cells 300 of FIG. 6C (i.e., horizontally oriented rather than vertically oriented as in FIG. 6C), and are connected in series with direct cell-to-cell bonding (e.g., at interface 405). Since in FIG. 7C three cells 400 are connected in series instead of four cells as in FIG. 6C, a lower voltage Vₜₒₜₐₗ of 1.5 V is generated but with the same current Iₜₒₜₐₗ of 5.75 A. Exit ribbons 450 are coupled to the solar cell array at either end of and on the long side of the assembly 420. The aperture fill is approximately 50%, as determined by the ability of the aspect ratio of the cells 400 to fit into the aperture 410 in this horizontal orientation.

FIGS. 8A-8B show the same size cell 500 and aperture area 510 as in FIGS. 7A-7B. Thus, H=5.31″, W=6.46″, Vₘₚₚ˜0.45 V and Iₘₚₚ˜5.75 A. The aperture 510 may represent, again, a shingle with glass. However, in the assembly 520 of FIG. 8C, the three cells 500 are oriented vertically rather than horizontally as in FIG. 7C. In FIG. 8C, three cells 500 are connected in series with direct cell-to-cell bonding (e.g., at interface 505). Exit ribbons 550 are at either end of the solar cell array. Because the cell size 500 and aperture size 510 are the same as in FIG. 7C, the same outputs result: Vₜₒₜₐₗ˜1.5 V, Iₜₒₜₐₗ˜5.75 A, and aperture fill ˜50%. However, the spacing arrangement in the final product assembly 520 is different. This could be an important factor for an installer who has to determine how to overlap the product to mimic a roofing component. Thus, FIG. 8C demonstrates how tailoring cell size and arrangement enables a user to choose the orientation that maximizes the aperture of an installed product rather than a standalone roofing solar product.

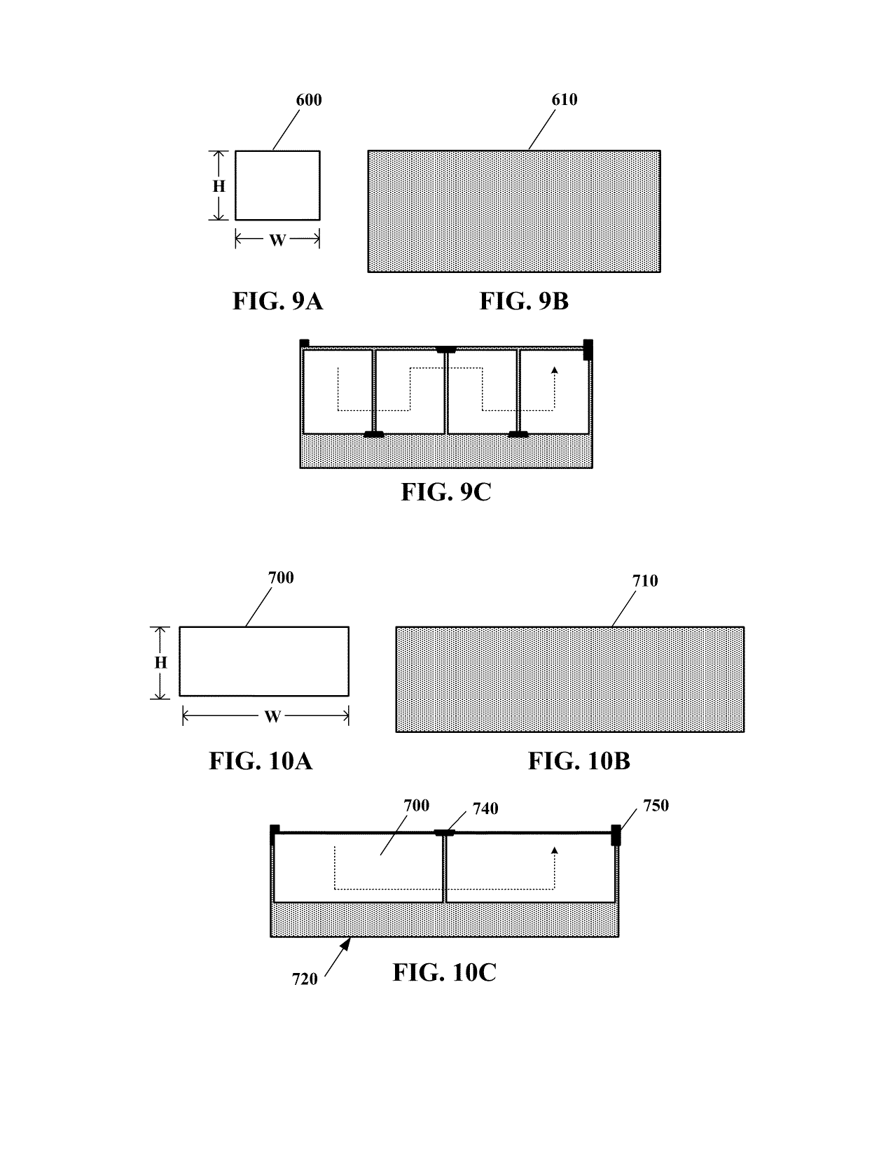

FIGS. 9A-9C show a similar configuration as FIGS. 6A-6C, with the cell 600 being the same size (H=5.31″, W=6.46″, Vₘₚₚ˜0.45 V and Iₘₚₚ˜5.75 A) but with a larger sheet of glass 610. Thus, the aperture fill is reduced to 70% in FIG. 9C compared with 98% in FIG. 6C.

FIG. 10A shows a cell 700 similar to those described to FIGS. 6-9 but the width has been doubled to 13″. Therefore, cell 700 has twice the surface area and twice the current. That is, H=5.31″, W=13″, Vₘₚₚ˜0.45 V and Iₘₚₚ˜11.53 A. Aperture 710 in FIG. 10B is larger than in previous embodiments to demonstrate use of a larger sized solar cell 700 for customizing the electrical output of the assembly 720, The aperture fill is approximately 70%. Terminal edges remain on the longer side but now there is only a single cross-connection 740 plus two the exit ribbons 750. As cross-connections cause potential resistance loss, a single cross-connection may be beneficial. The result of these two cells connected serially in assembly 720 is a Vₜₒₜₐₗ of ˜1 V and an Iₜₒₜₐₗ of ˜11.5 A.

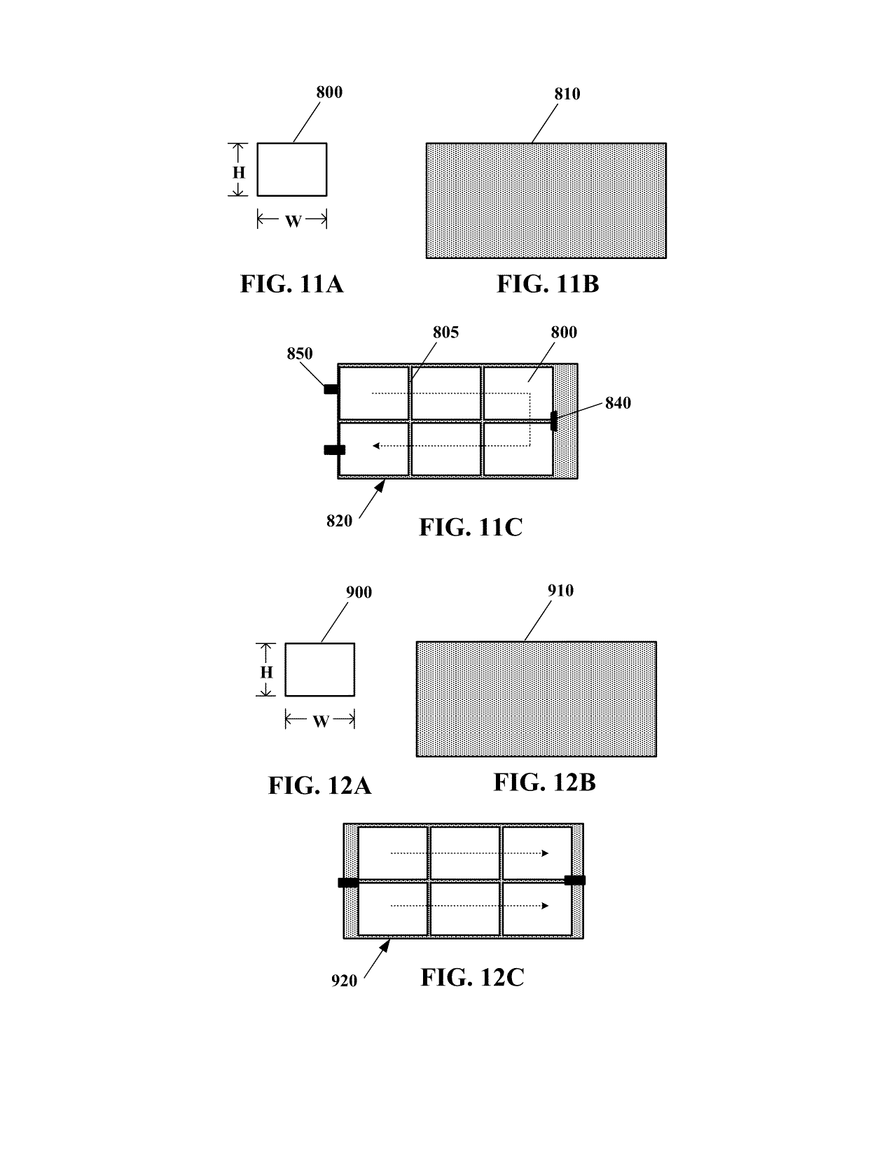

FIG. 11A shows a cell 800 similar to those of FIGS. 6-9 but in which the height has been reduced to 4.6″. The width remains at 6.46″. Thus, the cell 800 has a surface area with approximately 87% of the surface area of FIGS. 6-9, resulting in a voltage Vₘₚₚ of 0.45 V and a current Iₘₚₚ of 4.98 A in this embodiment. In the assembled roofing element 820 of FIG. 11C, six cells 800 are positioned on aperture 810 (FIG. 11B) and are connected in series with four cell-to-cell connections (e.g., at interface 805) and one cross-connector 840. Terminal edges 850 are now on a single short side of the roofing tile. The result of these six smaller cells 800, in connected serially, is a Vₜₒₜₐₗ of approximately 3.0 V and an Iₜₒₜₐₗ of 4.98 A. The aperture fill is ˜90%.

The sizes of cell 900 and aperture 910 in FIGS. 12A-12B are the same as FIGS. 11A-11B, but in FIG. 12C two three-cell strings of cells 900 are connected in parallel instead of six cells in one series string. Thus, for the cell 900 which has H=4.6″, W=6.46″, Vₘₚₚ˜0.45 V and Iₘₚₚ˜4.98 A, the array 920 has an electrical output which is approximately Vₜₒₜₐₗ=1.5 V and Iₜₒₜₐₗ=10 A. FIG. 12C illustrates that a different electrical output is created compared with FIG. 11C, even though the same cell size and layout is used. The aperture fill remains at 90% as in FIG. 11C.

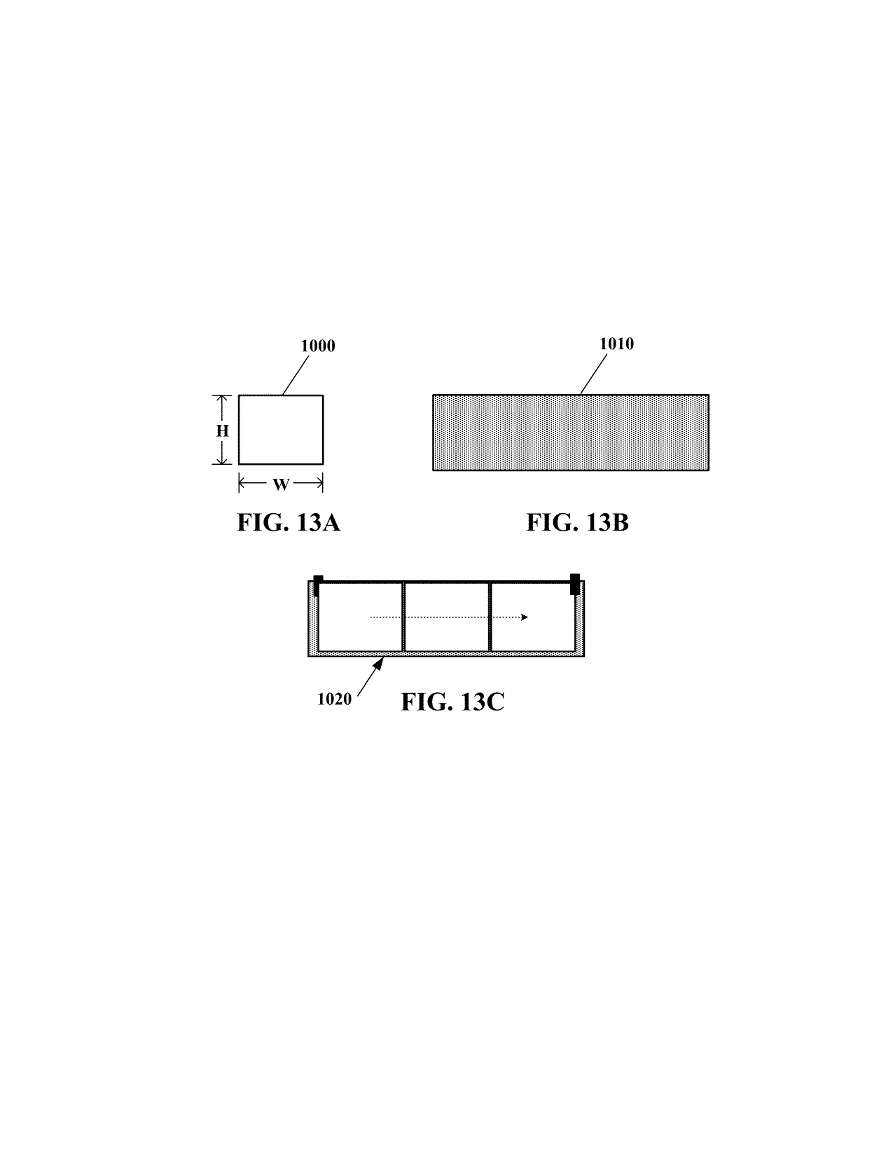

FIG. 13A has a cell 1000 which is the same size as in FIG. 7A but with a smaller piece of glass 1010 in FIG. 13B. The cell 1000 has the same parameters as in FIG. 7A: H=5.31″, W=6.46″, Vₘₚₚ˜0.45 V and Iₘₚₚ˜5.75 A. Consequently, the aperture fill of the assembly 1020 increases from 50% in FIG. 7C to 90% in FIG. 13C. The electrical outputs in FIG. 13C remain the same as in FIG. 7C, at Vₜₒₜₐₗ=1.5 V and Iₜₒₜₐₗ=5.75 A.

Thus, the various arrangements of FIGS. 6-13 demonstrate that electrical characteristics of a solar roofing element may be varied by changing electrical string configurations, while optimizing aperture fill by tailoring individual solar cell sizes and aspect ratios. Depending on the size and electrical characteristics of the solar cells material, and the size of the roofing element on which the solar array is to be installed may be tailored to have total currents of, for example, 1.0 to 15.0 A and total voltages of 1.0 to 5.0 V, although other values may be possible. Such flexibility enables tailoring a roofing element to meet the specified cost, performance, and efficiency requirements of a user.

Variations of the connectors described herein are possible. For example, the housing of a connector could be made of any material by any method. The connector could be designed for hand assembly or automated assembly, with or without locating features. The connector could be designed without the channel and holes to allow potting. The connector could be designed to allow two or more connectors to exit the solar module, and could include a diode linked between the exiting conductors. In one embodiment, both electrical leads or edge connectors are on the same side of module. In another embodiment, they are on different sides. In a still further embodiment, they are diagonal from each other. In yet another embodiment, they are on opposing sides. Optionally, in such a configuration, the top sheet may be a flexible top sheet such as that set forth in U.S. patent application Ser. No. 60/806,096 (Attorney Docket No. NSL-085P) entitled “Improved Encapsulant Layer for Photovoltaic Devices,” filed Jun. 28, 2006 and fully incorporated herein by reference for all purposes. It should also be understood that embodiments of the present invention may also be used with a central junction box and are not limited to only edge exiting electrical connectors. The modules may be mounted in either landscape or portrait orientation, with edge connectors located as appropriate to minimize distance to the closes adjacent module. It should also be understood that some embodiments of the module may have no pottant layers.

While the invention has been described and illustrated with reference to certain particular embodiments thereof, those skilled in the art will appreciate that various adaptations, changes, modifications, substitutions, deletions, or additions of procedures and protocols may be made without departing from the spirit and scope of the invention.

Additionally, concentrations, amounts, and other numerical data may be presented herein in a range format. It is to be understood that such range format is used merely for convenience and brevity and should be interpreted flexibly to include not only the numerical values explicitly recited as the limits of the range, but also to include all the individual numerical values or sub-ranges encompassed within that range as if each numerical value and sub-range is explicitly recited. For example, a thickness range of about 1 nm to about 200 nm should be interpreted to include not only the explicitly recited limits of about 1 nm and about 200 nm, but also to include individual sizes such as but not limited to 2 nm, 3 nm, 4 nm, and sub-ranges such as 10 nm to 50 nm, 20 nm to 100 nm, etc.

The publications discussed or cited herein are provided solely for their disclosure prior to the filing date of the present application. Nothing herein is to be construed as an admission that the present invention is not entitled to antedate such publication by virtue of prior invention. Further, the dates of publication provided may be different from the actual publication dates which may need to be independently confirmed. All publications mentioned herein are incorporated herein by reference to disclose and describe the structures and/or methods in connection with which the publications are cited.

While the above is a complete description of the preferred embodiment of the present invention, it is possible to use various alternatives, modifications and equivalents. Therefore, the scope of the present invention should be determined not with reference to the above description but should, instead, be determined with reference to the appended claims, along with their full scope of equivalents. Any feature, whether preferred or not, may be combined with any other feature, whether preferred or not. In the claims that follow, the indefinite article “A”, or “An” refers to a quantity of one or more of the item following the article, except where expressly stated otherwise. The appended claims are not to be interpreted as including means-plus-function limitations, unless such a limitation is explicitly recited in a given claim using the phrase “means for.”

What is claimed is:

1. A roofing element comprising:
a solar cell array comprising a plurality of low series resistance solar cells, wherein the low series resistance is based on a metallization-wrap-through (MWT) solar cell architecture, wherein each solar cell has a cell aspect ratio, and wherein the solar cells are electrically connected in an electrical string configuration by a low resistance cell-to-cell bonding method; and
a roofing material having a top surface, wherein the top surface comprises an opening having an aperture area, wherein the solar cell array is positioned in the opening, and wherein the amount of aperture area covered by the solar cell array comprises an aperture fill;
wherein the cell aspect ratio and the electrical string configuration are tailored to achieve a specified total current and total voltage for the solar cell array while optimizing the aperture fill.

2. The roofing element of claim 1 wherein the series resistance is less than 1 Ohm/cm².

3. The roofing element of claim 1 wherein the roofing material is a tile, shingle, or other modular roofing construct.

4. The roofing element of claim 1 wherein the low series resistance solar cells comprise an aluminum layer.

5. The roofing element of claim 1 wherein the MWT architecture is created by roll-to-roll processing on an aluminum foil substrate and a second foil.

6. The roofing element of claim 1 wherein the low resistance solar cells are grown on a highly conductive substrate, wherein the highly conductive substrate has a resistivity less than 1×10⁻⁸ Ohm-m.

7. The roofing element of claim 1 wherein the cell-to-cell bonding method comprises laser welding.

8. The roofing element of claim 1 wherein the cell-to-cell bonding method comprises ultrasonic welding.

9. The roofing element of claim 1 wherein the cell-to-cell bonding method comprises solder bonding.

10. The roofing clement of claim 1 wherein the cell-to-cell bonding method comprises conductive adhesive bonding.

11. The roofing element of claim 1 further comprising electrical exit terminals coupled to the solar cell array.

12. The roofing element of claim 11 wherein the electrical exit terminals comprise exit ribbon connections, and wherein the exit ribbon connections are coupled to the solar cell array by a low resistance bonding method.

13. The roofing element of claim 12 wherein the low resistance bonding method of the exit ribbon connections is chosen from the group consisting of laser welding, ultrasonic welding, solder bonding, and conductive adhesive bonding.

14. The roofing element of claim 1 wherein the cell aspect ratio is between 0.2 to 4.0.

15. The roofing element of claim 1 wherein the electrical string configuration is a series connection or a parallel connection.

16. The roofing element of claim 1 wherein the total current has a value between 1.0 to 15.0 amperes.

17. The roofing element of claim 1 wherein the total voltage has a value between 1.0 to 5.0 volts.

18. The roofing element of claim 1 wherein the aperture fill has a value between 50% to 100%.

19. The roofing element of claim 1 wherein solar cell has a width and a height, wherein the width is measured across the in-plane edges of the cell that form electrical connections, and wherein the aspect ratio is defined as the width divided by the height.
